(19) United States
(12) Patent Application Publication
(10) Pub. No.: US 2024/0304759 A1
(43) Pub. Date: Sep. 12, 2024

(54) LIGHT EMITTING DEVICE AND LIGHT EMITTING APPARATUS

(71) Applicant: QUANZHOU SANAN SEMICONDUCTOR TECHNOLOGY CO., LTD, Nanan City (CN)

(72) Inventors: Weiping XIONG, Tianjin (CN); Xin WANG, Tianjin (CN); Zhiwei WU, Tianjin (CN); Di GAO, Tianjin (CN); Yu-Ren PENG, Tianjin (CN); Huan-shao KUO, Tianjin (CN)

(21) Appl. No.: 18/667,346

(22) Filed: May 17, 2024

Related U.S. Application Data
(63) Continuation-in-part of application No. PCT/CN2022/127918, filed on Oct. 27, 2022.

(30) Foreign Application Priority Data
Nov. 26, 2021 (CN) 202111416529.8

(51) Int. Cl. H01L 33/38; H01L 33/00; H01L 33/32; H01L 33/40; H01L 33/46

(52) U.S. Cl. CPC H01L 33/38; H01L 33/0075; H01L 33/40; H01L 33/46; H01L 33/0093; H01L 33/32; H01L 2933/0016

(57) ABSTRACT

A light-emitting device includes a semiconductor epitaxial unit, a first contact electrode, and a second contact electrode. The semiconductor epitaxial unit includes a first semiconductor layer, a second semiconductor layer, and an active layer. The first contact electrode and the second contact electrode are disposed on the semiconductor epitaxial unit, and are electrically connected to the first semiconductor layer and the second semiconductor layer, respectively. The first contact electrode includes an ohmic contact layer and a first electrode barrier layer. The second contact electrode includes an ohmic contact layer and a second electrode barrier layer. The ohmic contact layer of the first contact electrode includes a first ohmic contact layer. The ohmic contact layer of the second contact electrode includes a second ohmic contact layer. The second contact electrode further includes another first ohmic contact layer disposed between the second ohmic contact layer and the second electrode barrier layer.

### CROSS-REFERENCE TO RELATED APPLICATION

This application is a continuation-in-part (CIP) of International Application No. PCT/CN2022/127918, filed on Oct. 27, 2022, which claims priority to Chinese Invention Patent Application No. 202111416529.8, filed on Nov. 26, 2021. The aforesaid applications are incorporated by reference herein in their entirety.

### FIELD

The disclosure relates to semiconductor technology, and more particularly to a light-emitting device and a light-emitting apparatus.

### BACKGROUND

In a light-emitting diode, which includes a light-emitting material, electrons and holes are recombined, thereby generating energy that is then converted to light emitted by the light-emitting device. Compared to a conventional electrical lighting method, the light-emitting diode offers advantages including high luminous intensity, high efficiency, small size, and long lifespan, and therefore is one of the light sources having the most potential. The light-emitting diode is widely used in areas such as lighting, signal display, backlighting, vehicle headlights, and large screen display.

Currently, in the light-emitting diode, an etched angle of a wall of an insulation layer 960 which defines a through hole is not optimal, and the wall is not even, thereby generating a gap between the insulation layer 960 and a pad electrode 932, 942 which is formed in the through hole. Referring to FIG. 1, when a solder paste or a tin electrode is used in the light-emitting diode, tin may easily enter through the gap, thereby corroding a gold-containing ohmic electrode 931, 941 beneath the through hole and affecting reliability of the light-emitting diode.

### SUMMARY

Therefore, an object of the disclosure is to provide a light-emitting device that can alleviate at least one of the drawbacks of the prior art.

According to the disclosure, the light-emitting device includes a semiconductor epitaxial unit, a first contact electrode, and a second contact electrode.

The semiconductor epitaxial unit has a first surface and a second surface that are opposite to each other, and includes a first semiconductor layer, a second semiconductor layer, and an active layer that is disposed between the first semiconductor layer and the second semiconductor layer.

The first contact electrode and the second contact electrode are disposed on the first surface of the semiconductor epitaxial unit, and are electrically connected to the first semiconductor layer and the second semiconductor layer, respectively.

The first contact electrode includes an ohmic contact layer, and a first electrode barrier layer disposed on the ohmic contact layer of the first contact electrode.

The second contact electrode includes an ohmic contact layer, and a second electrode barrier layer disposed on the ohmic contact layer of the second contact electrode.

The ohmic contact layer of the first contact electrode includes a first ohmic contact layer.

The ohmic contact layer of the second contact electrode includes a second ohmic contact layer. The second contact electrode further includes another first ohmic contact layer disposed between the second ohmic contact layer and the second electrode barrier layer.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic cross sectional view illustrating a conventional light-emitting device.

FIG. 2 is a schematic cross sectional view illustrating an embodiment of a light-emitting device according to the disclosure.

FIG. 3 is a schematic cross sectional view illustrating another embodiment of the light-emitting device according to the disclosure.

FIGS. 4 to 12 are schematic diagrams illustrating a method for manufacturing the embodiment of the light-emitting device according to the disclosure.

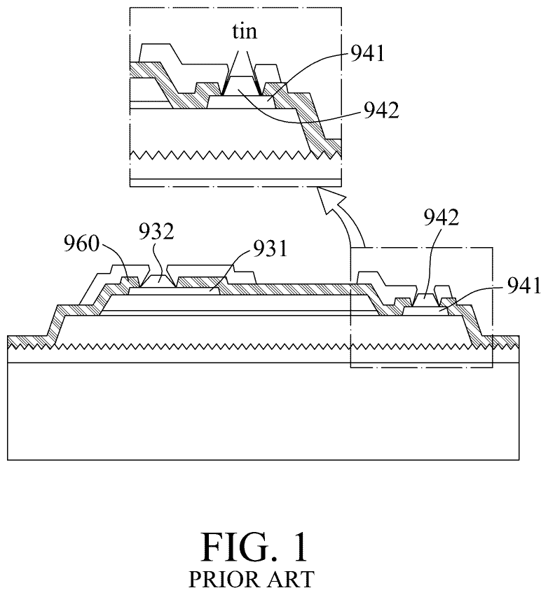

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

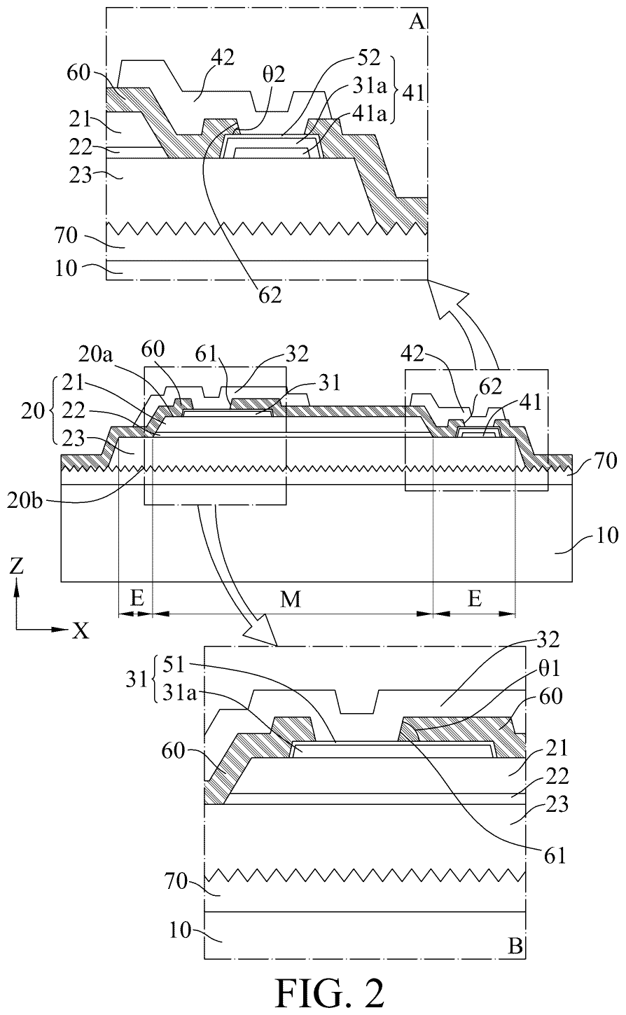

FIG. 2 is a schematic cross sectional view illustrating an embodiment of a light-emitting device according to the disclosure.

Referring to FIG. 2, to achieve at least one advantage brought by the disclosure, the embodiment of the light-emitting device is provided and includes a supporting substrate 10, a semiconductor epitaxial unit 20, a first contact electrode 31, a second contact electrode 41, and a bonding layer 70.

The light-emitting device may be a light-emitting chip of a conventional size that has a horizontal cross-sectional area ranging from 90,000 μm² approximately to 2,000,000 μm² approximately.

The light-emitting device may also be a light-emitting chip of a small size that has a horizontal cross-sectional area smaller than 90,000 μm² approximately. For example, the light-emitting device may have a length and/or a width ranging from 100 μm to 300 μm, and a thickness ranging from 40 μm to 100 μm.

The light-emitting device may even be a light-emitting chip of yet an even smaller size that has a horizontal cross-sectional area smaller than 10,000 μm² approximately. For example, the light emitting device may have a length and/or a width ranging from 2 μm to 100 μm, and a thickness ranging from 2 μm to 100 μm. The embodiment of the light-emitting device may have any of the horizontal cross-sectional areas and the thicknesses as described above, so it may be easily applied to small and micro light-emitting apparatus in an electronic device.

Referring again to FIG. 2, the semiconductor epitaxial unit 20 has a first surface 20a and a second surface 20b that are opposite to each other, and includes a first semiconductor layer 21, a second semiconductor layer 23, and an active layer 22 that is disposed between the first semiconductor layer 21 and the second semiconductor layer 23. In this embodiment, the first surface 20a is an upper surface of the first semiconductor layer 21, and the second surface 20b is a lower surface of the second semiconductor layer 23.

The first semiconductor layer 21 and the second semiconductor layer 23 have different conductivity types, electrical properties, polarities, and doping elements for providing electrons or holes, i.e., the first semiconductor layer 21 has a first conductivity type, the second semiconductor layer 23 has a second conductivity type, and the first conductivity type differs from the second conductivity type. For example, the first semiconductor layer 21 may be an n-type semiconductor layer, and the second semiconductor layer 23 may be a p-type semiconductor layer. Under an applied current, electrons from the n-type semiconductor layer and holes from the p-type semiconductor layer are recombined, thereby converting electrical energy into light energy, which is then emitted.

In this embodiment, the semiconductor epitaxial unit 20 includes a gallium arsenide (GaAs)-based material. The first semiconductor layer 21 is doped with an n-type dopant, and the second semiconductor layer 23 is doped with a p-type dopant.

In some embodiments, the first semiconductor layer 21 includes II-VI semiconductor materials (e.g., zinc selenide (ZnSe)) or Ill-V semiconductor materials (e.g., gallium arsenide (GaAs), gallium nitride (GaN), aluminum nitride (AlN), indium nitride (InN), indium gallium nitride (InGaN), aluminum gallium nitride (AlGaN), or aluminum indium gallium nitride (AlInGaN)). The first semiconductor layer 21 may also include a dopant such as silicon (Si), germanium (Ge), etc, but is not limited thereto. In other embodiments, the first semiconductor layer 21 has a single-layered structure or a multilayered structure.

In some embodiments, the second semiconductor layer 23 includes III-V semiconductor materials (e.g., gallium arsenide (GaAs), gallium nitride (GaN), aluminum nitride (AlN), indium nitride (InN), indium gallium nitride (InGaN), aluminum gallium nitride (AlGaN), or aluminum indium gallium nitride (AlInGaN)). The second semiconductor layer 23 may also include a dopant such as magnesium (Mg), carbon (C), etc, but is not limited thereto. In other embodiments, the second semiconductor layer 23 has a single-layered structure or a multilayered structure.

In this embodiment, the active layer 22 includes a gallium arsenide (GaAs)-based semiconductor material, an aluminum indium gallium phosphide (AlGaInP)-based material or an aluminum gallium indium nitride (AlGaInN)-based material. Specifically, when the active layer 22 includes the aluminum indium gallium phosphide (AlGaInP)-based material or the gallium arsenide (GaAs)-based material, the active layer 22 may emit red light, orange light, or yellow light. When the active layer 22 includes the aluminum gallium indium nitride (AlGaInN), the active layer 22 may emit blue light or green light. In some embodiments, the active layer 22 includes at least an un-doped semiconductor layer or at least a low-doped layer. In some embodiments, the active layer 22 may have a single heterostructure (SH), a double heterostructure (DH), a double-sided double heterostructure (DDH), or a multilayer quantum well structure (MQW), but is not limited thereto.

Referring again to FIG. 2, the bonding layer 70 bonds the second surface 20b of the semiconductor epitaxial unit 20 to the supporting substrate 10. In this embodiment, the supporting substrate 10 is a sapphire substrate. The supporting substrate 10 may be a transparent substrate, and include an inorganic material or an III-V semiconductor material. The inorganic material includes silicon carbide (SiC), germanium (Ge), sapphire, lithium aluminate (LiAlO₂), zinc oxide (ZnO), glass, or quartz. The III-V semiconductor material includes indium phosphide (InP), gallium phosphide (GaP), gallium nitride (GaN), and aluminum nitride (AlN). The supporting substrate 10 has sufficient strength to support the semiconductor epitaxial unit 20, and light emitted from the semiconductor epitaxial unit 20 may travel through the supporting substrate 10. In some embodiments, a thickness of the supporting substrate 10 is no smaller than 50 μm. In addition, to facilitate further mechanical processing of the supporting substrate 10 after bonding the semiconductor epitaxial unit 20 to the supporting substrate 10, the thickness of the supporting substrate 10 may be no greater than 300 μm.

It should be noted that the light-emitting device is not limited to include only one semiconductor epitaxial unit 20, but may include a plurality of semiconductor epitaxial units 20 on the supporting substrate 10. The plurality of semiconductor epitaxial units 20 may be electrically connected to each other in a series, in parallel, or in series-parallel combination through a conducting structure (e.g., wires).

Referring back to FIG. 2, in this embodiment, the bonding layer 70 covers the second surface 20b of the semiconductor epitaxial unit 20. The second surface 20b of the semiconductor epitaxial unit 20 is bonded to the supporting substrate 10 by the bonding layer 70, and the light emitted from the active layer 23 travels through the bonding layer 70 and the supporting substrate 10. In this embodiment, a light-exiting surface of the light-emitting device is a surface of the supporting substrate 10 away from the semiconductor epitaxial unit 20.

The bonding layer 70 may be made of an insulating material and/or a conductive material. The insulating material may include, but not limited to, polyimide (PI), benzocyclobutene (BCB), perflurocyclobutane (PFCB), magnesium oxide (MgO), Su₈, epoxy, acrylic resin, cyclic olefin copolymer (COC), polymethylmethacrylate (PMMA), polyethylene terephthalate (PET), polycarbonate (PC), polyetherimide, fluorocarbon polymer, glass, aluminum oxide (Al₂O₃), silicon oxide (SiOₓ), titanium oxide (TiO₂), tantalum oxide (Ta₂O₅), silicon nitride (SiNₓ), or Spin-on Glass (SoG). The conductive material may include, but not limited to, indium tin oxide (ITO), indium oxide (InO), tin oxide (SnO), cadmium tin oxide (CTO), antimony tin oxide (ATO), aluminum zinc oxide (AZO), zinc tin oxide (ZTO), zinc oxide (ZnO), indium zinc oxide (IZO), diamond-like carbon film (DLC), or gallium zinc oxide (GZO). When the bonding layer 70 is the conductive material and is in contact with the second semiconductor layer 23, it may function as a current spreading layer, thereby improving current spreading and enhancing uniformity of current distribution.

In some embodiments, the second surface 20b of the semiconductor epitaxial unit 20 that is proximate to the supporting substrate 10 may be a roughened surface that reduces total reflection of the light emitted from the active layer 22 and passing through the second surface 20b and the bonding layer 70.

In some embodiments, a refractive index of the bonding layer 70 ranges between a refractive index of the second semiconductor layer 23 and a refractive index of the supporting substrate 10. For example, the refractive index of the second semiconductor layer 23 is n1, the refractive index of the bonding layer 70 is n2, the refractive index of the supporting substrate 10 is n3, and n1>n2>n3. In certain embodiments, the refractive index of the bonding layer 70 ranges from 1.2 to 3.

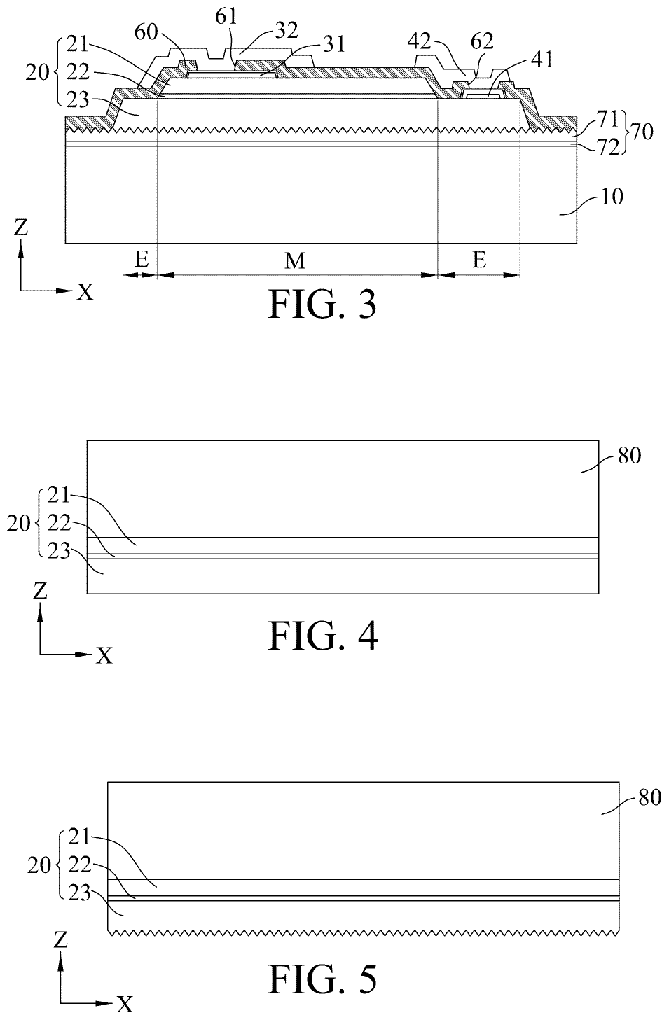

Referring to FIG. 3, in some embodiments, the bonding layer 70 has a stacked structure that has at least two layers. For example, the bonding layer 70 includes a first bonding layer 71 proximate to the second semiconductor layer 23, and a second bonding layer 72 distal from the second semiconductor layer 23. In one embodiment, the first bonding layer 71 is adjacent to the second semiconductor layer 23, while the second bonding layer 72 is adjacent to the supporting substrate 10. The first bonding layer 71 and the second bonding layer 72 are sequentially formed on the second semiconductor layer 23, thereby forming the bonding layer 70. For example, the first bonding layer 71 may be a transparent conductive layer that may act as a current spreading layer, and the second bonding layer 71 may be a bonding material layer that bonds the semiconductor epitaxial unit 20 to the supporting substrate 10.

In some embodiments, the bonding layer 70 has a gradient refractive index. A refractive index m1 of the first bonding layer 71 proximate to the second semiconductor layer 23 is different from a refractive index m2 of the second bonding layer 72 distal from the second semiconductor layer 23. In other words, the refractive indices of the second semiconductor layer 23, the bonding layer 70, and the supporting substrate 10 exhibit a continuous or stepwise change from the refractive index n1, the refractive index m1, the refractive index m2, the refractive index n2, to the refractive index n3. By virtue of varying the refractive indices, a travelling path of the light emitted from the active layer 23 to the substrate 10 changes, thereby reducing a likelihood of total reflection and avoiding the light being trapped inside the light-emitting device.

To dispose the first contact electrode 31 and the second contact electrode 41 on the first semiconductor layer 21 and the second semiconductor layer 23 at a same side of the semiconductor epitaxial unit 20, the second semiconductor layer 23 is disposed on the first semiconductor layer 21 in such a manner that a portion of the first semiconductor layer 21 is exposed from the second semiconductor layer 23, or the first semiconductor layer 21 is disposed on the second semiconductor layer 23 in such a manner that a portion of the second semiconductor layer 23 is exposed from the first semiconductor layer 21. For example, referring again to FIG. 2, in this embodiment, the semiconductor epitaxial unit 20 includes at least one recessed region (E) that is formed by partially removing the first semiconductor layer 21 and the active layer 22 to expose the second semiconductor layer 23. That is to say, in the recessed region (E), the first semiconductor layer 21 and the active layer 22 are completely removed, leaving only the second semiconductor layer 23. The semiconductor epitaxial unit 20 also includes a mesa region (M) in which the first semiconductor layer 21, the active layer 22, and the second semiconductor layer 23 are not etched. The recessed region (E) surrounds the mesa region (M). The mesa region (M) may have a relatively protruding shape along a Z-direction relative to the recessed region (E). In other words, the recessed region (E) may also be defined as a region that is etched, but is not limited thereto. In some embodiments, the first semiconductor layer 21, the active layer 22, and the second semiconductor layer 23 in the mesa region (M) are not etched, but a portion of the first semiconductor layer 21 and a portion of the active layer 22 in the recessed region (E) are removed. In some embodiments, the mesa region (M) may gradually taper in an upward direction perpendicular to the Z-direction. Thus, the mesa region (M) may have an inclined side surface along the Z-direction.

The light-emitting device includes at least one first contact electrode 31 that is disposed on the first semiconductor layer 21 and that is electrically connected to the first semiconductor layer 21 directly or indirectly, and at least one second contact electrode 41 that is disposed on the second semiconductor layer 23 and that is electrically connected to the second semiconductor layer 23 directly or indirectly. In the case where the first semiconductor layer 21 is the n-type semiconductor layer, the first contact electrode 31 is an n-type contact electrode; in the case where the first semiconductor layer 21 is the p-type semiconductor layer, the first contact electrode 31 is a p-type contact electrode. The first contact electrode 31 and the second contact electrode 41 are opposite to each other in conductivity types.

For example, in some embodiments, when pad electrodes (to be described below) of the light-emitting device do not include tin, and a solder paste is used in packaging, due to strong mobility of the tin (i.e., tin flows easily), the tin in the solder paste may easily enter through gaps between an insulation layer 60 (to be described later) and the pad electrodes and erode ohmic electrodes (i.e., the first contact electrode 31 and the second contact electrode 41) having Au, Sn, or In beneath, thereby affecting reliability of the light-emitting device. In other embodiments, when the pad electrodes include tin, the tin may enter through the gaps between the insulation layer 60 and the pad electrodes and erode the ohmic electrodes having Au, Sn, or In beneath, thereby affecting the reliability of the light-emitting device.

Each of the first contact electrode 31 and the second contact electrode 41 may be made of metals, e.g., nickel, gold, chromium, titanium, germanium, beryllium, platinum, palladium, rhodium, iridium, aluminum, tin, indium, tantalum, copper, cobalt, iron, ruthenium, zirconium, tungsten, molybdenum, zinc, or combinations thereof.

To solve the technical problem of tin (Sn) eroding the ohmic electrodes having gold generally, which may affect the reliability of the light-emitting device, in some embodiments, the first contact electrode 31 includes an ohmic contact layer and a first electrode barrier layer 51 disposed on the ohmic contact layer of the first contact electrode 31. The ohmic contact layer of the first contact electrode 31 includes a first ohmic contact layer 31a. In some embodiments, the first contact electrode 31 is the n-type contact electrode. The first electrode barrier layer 51 includes Ti, Pt, Cr or combinations thereof, but is not limited thereto. In some embodiments, the first electrode barrier layer 51 is an alloy layer including Ti, Pt, Cr, or combinations thereof. In other embodiments, the first electrode barrier layer 51 is a stacked layer structure including Ti, Pt, Cr, or combinations thereof. The first electrode barrier layer 51 may also be made of other metals, alloys of these other metals, or stacked layer structures of these other metals that do not react with tin (Sn).

The second contact electrode 41 includes an ohmic contact layer and a second electrode barrier layer 52 disposed on the ohmic contact layer of the second contact electrode 41. The ohmic contact layer of the second contact electrode 41 includes a second ohmic contact layer 41a. When the first ohmic contact layer 31a or another first ohmic contact layer 31a is an Au/Ge alloy layer, an Au/Ni alloy layer, an Au/Ge/Ni alloy layer, an Au/Ge stacked layer structure, an Au/Ni stacked layer structure, or an Au/Ge/Ni stacked layer structure, and when the second ohmic contact layer 41a is an Au/Be alloy layer, an Au/Zn alloy layer, an Au/Be/Zn alloy layer, an Au/Be stacked layer structure, an Au/Zn stacked layer structure, or an Au/Be/Zn stacked layer structure, due to the second ohmic contact layer 41a having Au and Be and/or Zn, fusion temperature of the second contact electrode 41 is over 500° C., and an electrode barrier layer thereof (i.e., the second electrode barrier layer 52) may not withstand such a high temperature; therefore, it is not possible to directly deposit the electrode barrier layer (i.e., the second electrode barrier layer 52) on the second ohmic contact layer 41a which is not yet fused. Instead, fusion of the second ohmic contact layer 41a needs to be completed first before vapor deposition of the electrode barrier layer thereon. Hence, the second contact electrode 41 includes the another first ohmic contact layer 31a disposed on the second ohmic contact layer 41a because fusion temperature of the another first ohmic contact layer 31a is lower. The another first ohmic contact layer 31a is formed after fusion of the second ohmic contact layer 41a, and covers the second ohmic contact layer 41a while being formed.

To further solve the technical problem of tin (Sn) eroding the ohmic electrodes having gold, which may affect the reliability of the light-emitting device, in this embodiment, the second contact electrode 41 includes the ohmic contact layer and the second electrode barrier layer 52 disposed on the ohmic contact layer of the second contact electrode 41. The second electrode barrier layer 52 includes Ti, Pt, Cr, or combinations thereof. In some embodiments, the second electrode barrier layer 52 is an alloy layer including Ti, Pt, Cr, or combinations thereof. In other embodiments, the second electrode barrier layer 52 is a stacked layer structure including Ti, Pt, Cr, or combinations thereof. The second electrode barrier layer 52 may also be made of other metals, alloys of these other metals, or stacked layer structures of these other metals that do not react with tin (Sn). In addition, in this embodiment, the first electrode barrier layer 51 and the second electrode barrier layer 52 are made of a same material, but are not limited thereto. The first electrode barrier layer 51 and the second electrode barrier layer 52 may also be made of different materials.

A thickness of the ohmic contact layer of the second contact electrode 41 is greater than a thickness of the ohmic contact layer of the first contact electrode 31. A thickness of each of the first electrode barrier layer 51 and the second electrode barrier layer 52 ranges from 0.1 μm to 1 μm. If the thicknesses of the first electrode barrier layer 51 and the second electrode barrier layer 52 are too small, the first electrode barrier layer 51 and the second electrode barrier layer 52 may be etched off during subsequent etching of the insulation layer 60, thereby losing their functions. If the thicknesses of the first electrode barrier layer 51 and the second electrode barrier layer 52 are too large, manufacturing costs may be increased.

Referring to the enlarged portions A and B in FIG. 2, specifically, in this embodiment, the first contact electrode 31 is the n-type contact electrode, and the second contact electrode 41 is the p-type contact electrode. The first contact electrode 31 includes the first ohmic contact layer 31a and the first electrode barrier layer 51 disposed on the first ohmic contact layer 31a, and the second contact electrode 41 includes the second ohmic contact layer 41a, the second electrode barrier layer 52 disposed on the second ohmic contact layer 41a, and the another first ohmic contact layer 31a disposed between the second ohmic contact layer 41a and the second electrode barrier layer 52. In this embodiment, after forming the second ohmic contact layer 41a on a top surface of the second semiconductor layer 23, the another first ohmic contact layer 31a is disposed on the second ohmic contact layer 41a to ensure vapor deposition of the second electrode barrier layer 52 on the first ohmic contact layer 31a, thereby preventing tin from entering through gaps at a through hole (to be described below) of the insulation layer 60 and eroding the second ohmic contact layer 41a beneath. In some embodiments, the ohmic contact layer of the first contact electrode 31 includes x1 number of metal layers, the ohmic contact layer of the second contact electrode 41 includes x2 number of metal layers, and x1<x2.

Referring again to the enlarged portion A in FIG. 2, in some embodiments, the another first ohmic contact layer 31a covers the second ohmic contact layer 41a completely, but is not limited thereto. By virtue of the another first ohmic contact layer 31a covering the second ohmic contact layer 41a completely, the first ohmic contact layer 31a is not deviated from its proper position, thereby avoiding exposure of a portion of the second ohmic contact layer 41a, and the reliability of the light-emitting device is thus ensured. In some embodiments, in the ohmic contact layer of the second contact electrode 41, the another first ohmic contact layer 31a covers at least a top surface of the second ohmic contact layer 41a; in some other embodiments, in the ohmic contact layer of the second contact electrode 41, the another first ohmic contact layer 31a may further cover a side surface of the second ohmic contact layer 41a. In yet some other embodiments, a thickness of the another first ohmic contact layer 31a covering the side surface of the second ohmic contact layer 41a is smaller than a thickness of the another first ohmic contact layer 31a covering the top surface of the second ohmic contact layer 41a.

The thickness of each of the first ohmic contact layer 31a and the another first ohmic contact layer 31a ranges from 0.1 μm to 2 μm. When the thickness of each of the first ohmic contact layer 31a and the another first ohmic contact layer 31a is too small, ohmic contact is difficult to be formed. When the thickness of each of the first ohmic contact layer 31a and the another first ohmic contact layer 31a is too large, it is difficult for the corresponding one of the first electrode barrier layer 51 and the second electrode barrier layer 52 to cover thereon. Each of the first ohmic contact layer 31a and the another first ohmic contact layer 31 may include Au, Ge, Ni, alloy combinations thereof, or stacked layer structures thereof. In this embodiment, each of the first ohmic contact layer 31a and the another first ohmic contact layer 31 is an Au/Ge/Ni stacked layer. In other embodiments, each of the first ohmic contact layer 31a and the another first ohmic contact layer 31 is a metallic layer having gold (Au) or an alloy layer having gold, but is not limited thereto. Each of the first ohmic contact layer 31a and the another first ohmic contact layer 31 may include Au and Ge or Ni, alloy combinations thereof, or stacked layer structures thereof, but is not limited thereto. Each of the first ohmic contact layer 31a and the another first ohmic contact layer 31 may also be made of other metals, alloys of these other metals, or stacked layer structures of these other metals that react with tin (Sn).

A thickness of the second ohmic contact layer 41a ranges from 0.1 μm to 2 μm. When the thickness of the second ohmic contact layer 41a is too small, ohmic contact is difficult to be formed. When the thickness of the second ohmic contact layer 41a is too large, it is difficult for the second electrode barrier layer 52 to cover the second ohmic contact layer 41a. The second ohmic contact layer 41a may include Au, Be, Zn, alloy combinations thereof, or stacked layer structures thereof. In this embodiment, the second ohmic contact layer 41a is an Au/Be stacked layer structure. In other embodiments, the second ohmic contact layer 41a is an Au/Zn stacked layer structure. In yet some other embodiments, the second ohmic contact layer 41a is a metallic layer having gold (Au) or an alloy layer having gold, but is not limited thereto. The second ohmic contact layer 41a may also include Au and Be or Zn, alloy combinations thereof, or stacked layer structures thereof, but is not limited thereto. The second ohmic contact layer 41a may also be made of other metals, alloys of these other metals, or stacked layer structures of these other metals that may react with tin (Sn).

The insulation layer 60 is disposed on a top surface (i.e., the first surface 20a) of the semiconductor epitaxial unit 20, covers at least a peripheral region and a sidewall of the semiconductor epitaxial unit 20, and includes a first through hole 61 and a second through hole 62. The insulation layer 60 also covers the first contact electrode 31 and the second contact electrode 41. At the same time, the insulation layer 60 may extend and partially cover a top surface of the bonding layer 70 that is exposed at the peripheral region of the semiconductor epitaxial unit 20. In such way, the insulation layer 60 may be connected to the top surface of the supporting substrate 10, thereby covering the sidewall of the semiconductor epitaxial unit 20 more securely.

The insulation layer 60 covering most of the top surface and the sidewall of the semiconductor epitaxial unit 20 may include a distributed Bragg reflector that reflects light, thereby increasing light-emitting efficiency of the light-emitting device. In addition, the insulation layer 60 extends from the semiconductor epitaxial unit 20 to partially cover the top surface of the bonding layer 70, and partially expose the top surface of the bonding layer 70. That is to say, a peripheral portion of the top surface of the supporting substrate 10 is not covered with the insulation layer 60. In such way, in a process of dicing a wafer to form a plurality of light-emitting devices, damage (e.g., peeling, cracking, etc.) to the insulation layer 60 caused by a laser or the like is prevented when dividing the supporting substrate 10 (e.g., dividing the supporting substrate 10 by cutting, scoring, and/or breaking). In particular, in the case where the insulation layer 60 includes the distributed Bragg reflector, when the insulation layer 60 is damaged, light reflectivity is reduced and electrical leakage is likely to occur. Configuration of the insulation layer 60 in this embodiment may prevent a decrease in the light-emitting efficiency and abnormality of the light-emitting device.

The embodiment of the light-emitting device further includes a first pad electrode 32 and a second pad electrode 42. The first pad electrode 32 is disposed on the insulation layer 60, and is electrically connected to the first contact electrode 31 via the first through hole 61. The second pad electrode 42 is disposed on the insulation layer 60, and is electrically connected to the second contact electrode 41 via the second through hole 62. Referring to FIG. 2, each of the first through hole 61 and the second through hole 62 may have a circular cross section. In other embodiments, each of the first through hole 61 and the second through hole 62 may have a square cross section. The shape of the cross section and the number of each of the first through hole 61 and the second through hole 62 are not limited (i.e., may be only one through hole or a plurality of through holes). The plurality of through holes may better facilitate distribution of current spreading. In other embodiments, in the case where the plurality of through holes exist, the through holes may be arranged in a spaced-apart manner by an equal distance, or by a non-equal distance, but are not limited thereto. In certain embodiments, each of the first pad electrode 32 and the second pad electrode 42 includes Ti, Al, Pt, Au, Ni, Sn, In or combinations thereof. In some embodiments, each of the first pad electrode 32 and the second pad electrode 42 is an alloy layer including Ti, Al, Pt, Au, Ni, Sn, In, or combinations thereof. In other embodiments, each of the first pad electrode 32 and the second pad electrode 42 is a stacked layer structure including Ti, Al, Pt, Au, Ni, Sn, In, or combinations thereof.

Referring to FIG. 2, in some embodiments, a width of a bottom opening of the first through hole 61 is smaller than a width of an upper surface of the first electrode barrier layer 51. The upper surface of the first electrode barrier layer 51 is located beneath the first through hole 61. That is to say, a projection of the bottom opening of the first through hole 61 on an imaginary plane parallel to the Z-direction falls within a projection of the upper surface of the first electrode barrier layer 51 on the imaginary plane, thereby protecting the first ohmic contact layer 31a underneath. In some embodiments, a difference between the width of the bottom opening of the first through hole 61 and the width of the upper surface of the first electrode barrier layer 51 is greater than 5 μm. If the difference is too small, the first through hole 61 may deviate from a position of the first electrode barrier layer 51.

Referring to FIG. 2, in some embodiments, a width of a bottom opening of the second through hole 62 is smaller than a width of an upper surface of the second electrode barrier layer 52. The upper surface of the second electrode barrier layer 52 is located beneath the second through hole 62. That is to say, a projection of the bottom opening of the second through hole 62 on an imaginary plane parallel to the Z-direction falls within a projection of the upper surface of the second electrode barrier layer 52 on the imaginary plane, thereby protecting the second ohmic contact layer 41a underneath. In some embodiments, a difference between the width of the bottom opening of the second through hole 62 and the width of the upper surface of the second electrode barrier layer 52 is greater than 5 μm. If the difference is too small, the second through hole 62 may deviate from a position of the second electrode barrier layer 52.

Each of the first through hole 61 and the second through hole 62 may have a tilted side surface. The tilted side surface of the first through hole 61 forms a first angle (θ1) with an upper surface of the first contact electrode 31, and the tilted side surface of the second through hole 62 forms a second angle (θ2) with an upper surface of the second contact electrode 41. The first angle (θ1) and the second angle (θ2) are formed outside the first through hole 61 and the second through hole 62, respectively. Each of the first angle (θ1) and the second angle (θ2) is no greater than 80°, thereby preventing the insulation layer 60 from breaking at the tilted side surfaces of the first through hole 61 and the second through hole 62.

The light-emitting device as described above is capable of emitting light having a wavelength ranging from 580 nm to 1000 nm.

Referring to FIGS. 4 to 12, a method for manufacturing the embodiment of the light-emitting device according to the disclosure is provided.

Referring to FIG. 4, the semiconductor epitaxial unit 20 is formed on a growth substrate 80 by methods such as metal organic chemical vapor deposition (MOCVD), molecular beam epitaxy (MBE), or hydride vapor phase epitaxy (HVPE). The growth substrate 80 is a GaAs substrate. The semiconductor epitaxial unit 20 is made of a gallium arsenide (GaAs)-based material, and includes the first semiconductor layer 21, the second semiconductor layer 23, and the active layer 22 disposed between the first semiconductor layer 21 and the second semiconductor layer 23.

Referring to FIG. 5, the lower surface of the second semiconductor layer 23 is roughened by a roughening process (e.g., etching or mechanical grinding, but is not limited thereto), thereby forming the roughened surface.

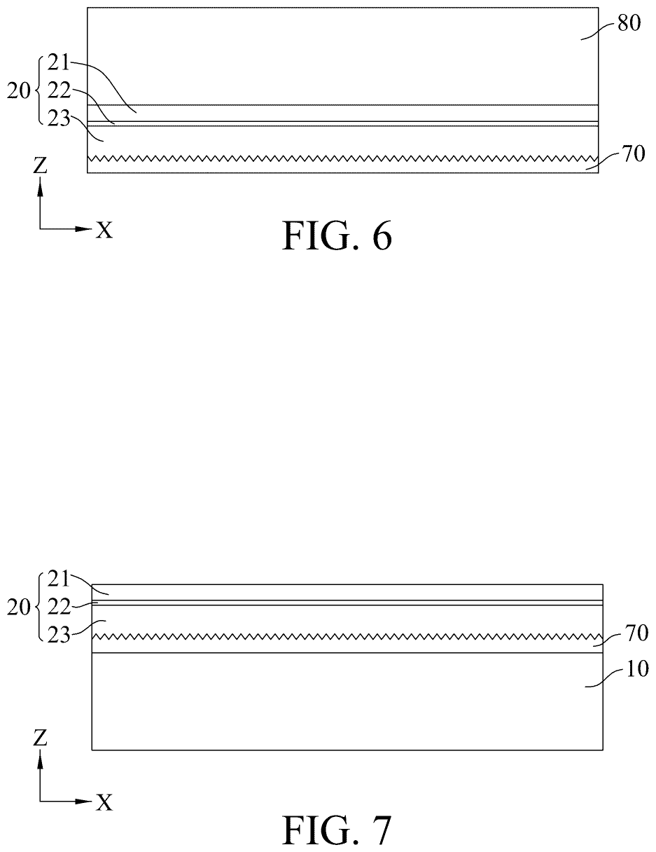

Referring to FIG. 6, the bonding layer 70 is deposited on the roughened surface of the second semiconductor layer 23, and is polished. The bonding layer 70 is made of silica.

Referring to FIG. 7, the growth substrate 80 is removed, and the semiconductor epitaxial unit 20 is bonded to the supporting substrate 10 by the bonding layer 70. The supporting substrate 10 is a sapphire substrate.

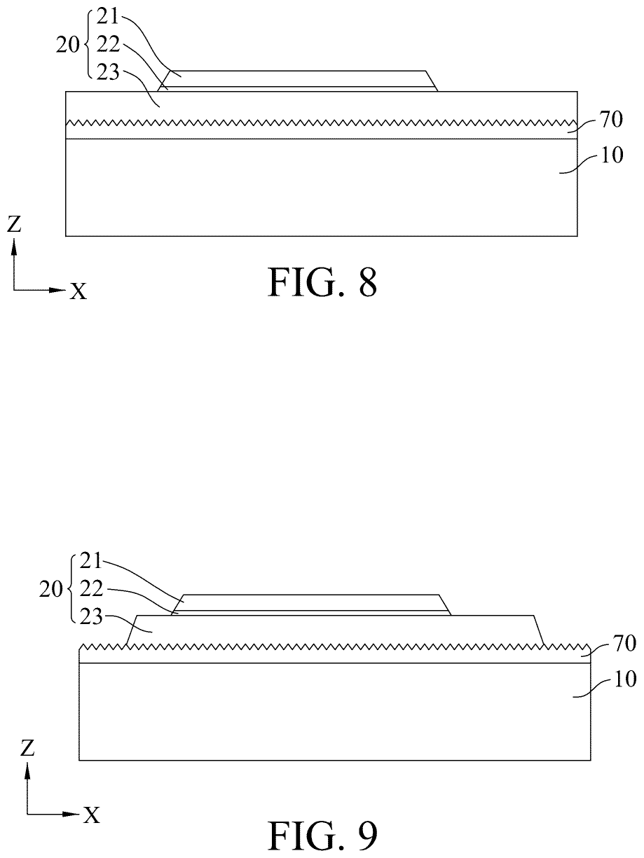

Referring to FIG. 8, a patterned photoresist (not shown) is formed on a top surface of the semiconductor epitaxial unit 20. A portion of the first semiconductor layer 21 and a portion of the active layer 22 are removed until a portion of the second semiconductor layer 23 is exposed so as to form the recessed region (E) and the mesa region (M) shown in FIG. 2.

Referring to FIG. 9, another patterned photoresist (not shown) is formed on the top surface of the semiconductor epitaxial unit 20, and a peripheral portion of the semiconductor epitaxial unit 20 of the light-emitting device is removed to form a cutting channel.

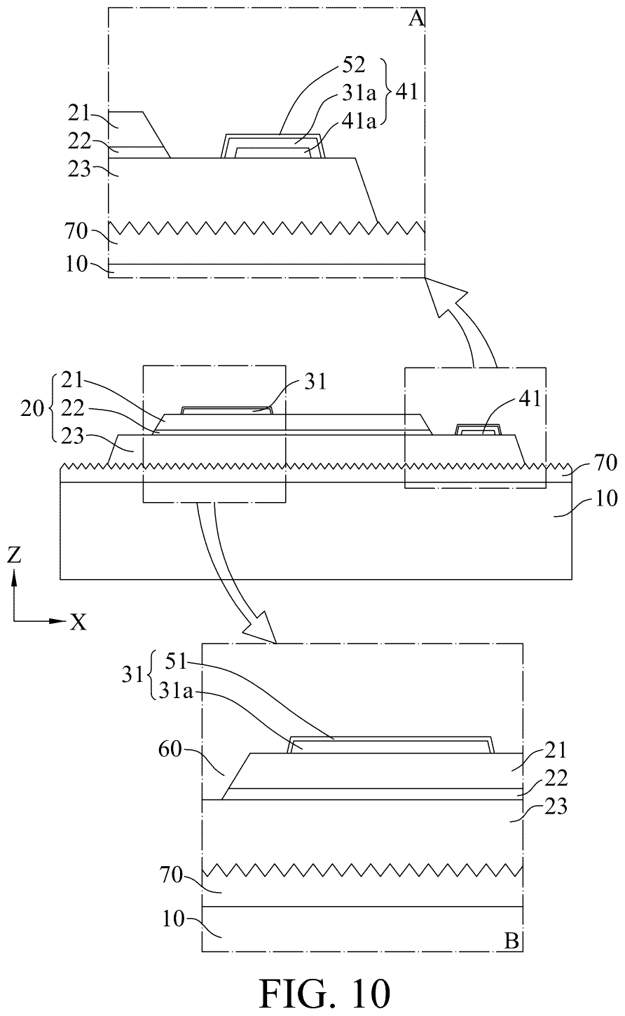

Referring to FIG. 10, the first contact electrode 31 and the second contact electrode 32 are formed on the top surface of the semiconductor epitaxial unit 20. Specifically, first, the second ohmic contact layer 41a is formed on the second semiconductor layer 23 in the recessed region (E), while forming the first ohmic contact layer 31a on the first semiconductor layer 21 in the mesa region (M) by vapor deposition, the another first ohmic contact layer 31a is formed on and covers the second ohmic contact layer 41a. Then, the first electrode barrier layer 51 and the second electrode barrier layer 52 are formed on the first ohmic contact layer 31a and the another first ohmic contact layer 31a, respectively. The first electrode barrier layer 51 and the second electrode barrier layer 52 may be formed at the same time or separately based on the materials needed, but are not limited thereto.

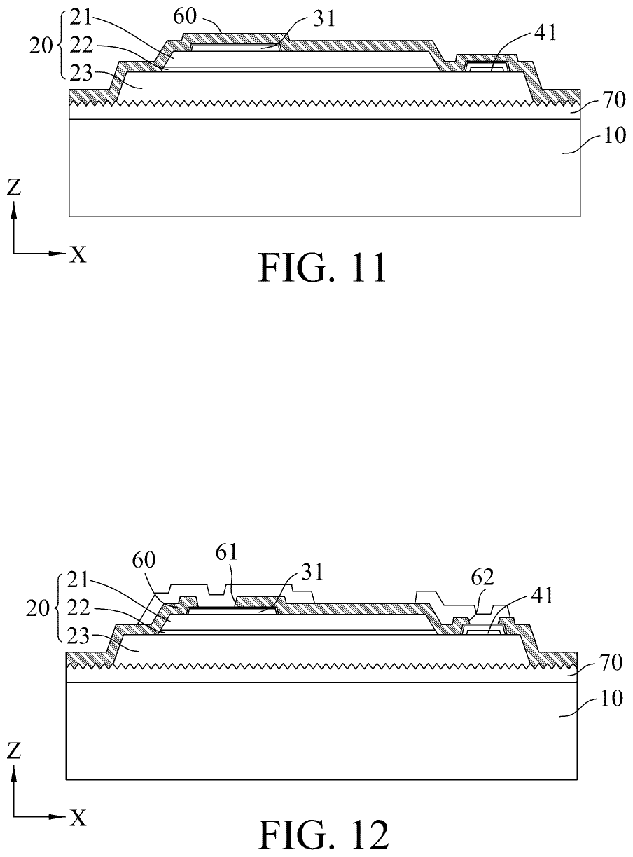

Referring to FIG. 11, the insulation layer 60 is deposited, which completely covers the top surface of the semiconductor epitaxial unit 20, the sidewall of the semiconductor epitaxial unit 20, and a top surface of the bonding layer 70 that is exposed.

Referring to FIG. 12, the first through hole 61 and the second through hole 62 are formed in the insulation layer 60 covering the first semiconductor layer 21 and the second semiconductor layer 23, respectively, and the first pad electrode 32 and the second pad electrode 42 are formed on the insulation layer 60 and are electrically connected to the first semiconductor layer 21 and the second semiconductor layer 23 via the first through hole 61 and the second through hole 62, respectively.

A light-emitting apparatus including the light-emitting device as described above is also provided.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A light-emitting device, comprising:
a semiconductor epitaxial unit having a first surface and a second surface that are opposite to each other, and including a first semiconductor layer, a second semiconductor layer, and an active layer that is disposed between said first semiconductor layer and said second semiconductor layer; and
a first contact electrode and a second contact electrode disposed on said first surface of said semiconductor epitaxial unit, and being electrically connected to said first semiconductor layer and said second semiconductor layer, respectively;
wherein
said first contact electrode includes an ohmic contact layer and a first electrode barrier layer disposed on said ohmic contact layer of said first contact electrode;
said second contact electrode includes an ohmic contact layer and a second electrode barrier layer disposed on said ohmic contact layer of said second contact electrode;
said ohmic contact layer of said first contact electrode includes a first ohmic contact layer;
said ohmic contact layer of said second contact electrode includes a second ohmic contact layer, said second contact electrode further including another first ohmic contact layer disposed between said second ohmic contact layer and said second electrode barrier layer.

2. The light-emitting device as claimed in claim 1, wherein a thickness of said ohmic contact layer of said second contact electrode is greater than a thickness of said ohmic contact layer of said first contact electrode.

3. The light-emitting device as claimed in claim 2, wherein said ohmic contact layer of said first contact electrode includes x1 number of metal layers, said ohmic contact layer of said second contact electrode includes x2 number of metal layers, and x1<x2.

4. The light-emitting device as claimed in claim 1, wherein in said ohmic contact layer of said second contact electrode, said another first ohmic contact layer covers at least a top surface of said second ohmic contact layer.

5. The light-emitting device as claimed in claim 4, wherein in said ohmic contact layer of said second contact electrode, said another first ohmic contact layer covers a side surface of said second ohmic contact layer.

6. The light-emitting device as claimed in claim 5, wherein in said ohmic contact layer of said second contact electrode, a thickness of said another first ohmic contact layer covering said side surface of said second ohmic contact layer is smaller than a thickness of said another first ohmic contact layer covering said top surface of said second ohmic contact layer.

7. The light-emitting device as claimed in claim 1, wherein said first electrode barrier layer and said second electrode barrier layer are made of a same material.

8. The light-emitting device as claimed in claim 1, wherein each of said first ohmic contact layer and said another first ohmic contact layer is an Au/Ge alloy layer, an Au/Ni alloy layer, an Au/Ge/Ni alloy layer, an Au/Ge stacked layer structure, an Au/Ni stacked layer structure, or an Au/Ge/Ni stacked layer structure.

9. The light-emitting device as claimed in claim 1, wherein a thickness of each of said first ohmic contact layer and said another first ohmic contact layer ranges from 0.1 μm to 2 μm.

10. The light-emitting device as claimed in claim 1, wherein said second ohmic contact layer is an Au/Be alloy layer, an Au/Zn alloy layer, an Au/Be/Zn alloy layer, an Au/Be stacked layer structure, an Au/Zn stacked layer structure, or an Au/Be/Zn stacked layer structure.

11. The light-emitting device as claimed in claim 1, wherein a thickness of said second ohmic contact layer ranges from 0.1 μm to 2 μm.

12. The light-emitting device as claimed in claim 1, wherein each of said first electrode barrier layer and said second electrode barrier layer includes Ti, Pt, Cr, or combinations thereof.

13. The light-emitting device as claimed in claim 1, wherein a thickness of each of said first electrode barrier layer and said second electrode barrier layer ranges from 0.1 μm to 1 μm.

14. The light-emitting device as claimed in claim 1, wherein a light emitted by said light-emitting device has a wavelength ranging from 580 nm to 1000 nm.

15. The light-emitting device as claimed in claim 1, further comprising
an insulation layer disposed on said semiconductor epitaxial unit that covers at least a peripheral region and a sidewall of said semiconductor epitaxial unit, and including a first through hole and a second through hole;
a first pad electrode disposed on said insulation layer and being electrically connected to said first contact electrode via said first through hole; and
a second pad electrode disposed on said insulation layer and being electrically connected to said second contact electrode via said second op through hole.

16. The light-emitting device as claimed in claim 15, wherein each of said first pad electrode and said second pad electrode includes Ti, Al, Pt, Au, Ni, Sn, In or combinations thereof.

17. The light-emitting device as claimed in claim 15, wherein
a width of a bottom opening of said first through hole is smaller than a width of an upper surface of said first electrode barrier layer, the upper surface of said first electrode barrier layer being located beneath said first through hole; and
a width of a bottom opening of said second through hole is smaller than a width of an upper surface of said second electrode barrier layer, the upper surface of said second electrode barrier layer being located beneath said second through hole.

18. The light-emitting device as claimed in claim 15, wherein each of said first through hole and said second through hole has a tilted side surface, said tilted side surface of said first through hole forming a first angle with an upper surface of said first contact electrode, said tilted side surface of said second through hole forming a second angle with an upper surface of said second contact electrode, said first angle and said second angle being formed outside said first through hole and said second through hole, respectively, each of said first angle and said second angle being no greater than 80°.

19. A light-emitting apparatus, comprising a light-emitting device as claimed in claim 1.
